(19) United States
(12) Patent Application Publication
(10) Pub. No.: US 2026/0068427 A1
(43) Pub. Date: Mar. 5, 2026

(54) ORGANIC LIGHT EMITTING ELEMENT

(71) Applicant: TAIZHOU GUANYU TECHNOLOGY CO., LTD., ZHEJIANG PROVINCE (CN)

(72) Inventors: HUEI-SIOU CHEN, TAIPEI CITY (TW); LI-CHEN WEI, TAICHUNG CITY (TW)

(21) Appl. No.: 19/258,916

(22) Filed: Jul. 3, 2025

(30) Foreign Application Priority Data
Sep. 3, 2024 (CN) 202411230860.4

(51) Int. Cl. H10K 50/15; H10K 50/13; H10K 50/16; H10K 50/17; H10K 102/00

(52) U.S. Cl. CPC H10K 50/156; H10K 50/131; H10K 50/166; H10K 50/17; H10K 2102/351

(57) ABSTRACT

An organic light emitting element includes a substrate, a first electrode, a second electrode, a first organic light emitting layer and a second organic light emitting layer. The first electrode and the second electrode are located over the substrate. The first organic light emitting layer is located over the first electrode. The second organic light emitting layer is located over the second electrode. A difference between a thickness of the second organic light emitting layer and a thickness of the first organic light emitting layer is greater than 500 angstrom (Å) and less than 1500 Å.

### BACKGROUND OF THE PRESENT DISCLOSURE

### Field of the Present Disclosure

The present disclosure relates to an organic light emitting element, and more particularly to an organic light emitting element including an organic light emitting diode (OLED) structure.

### Description of the Prior Art

Currently, a fine metal mask (FMM) is commonly used in a coating step for a light emitting layer of an organic light emitting element, or white light in combination with a color film are used for a manufacturing process. However, fineness or resolution of pixels resulted from the manufacturing process above is rather poor.

### SUMMARY OF THE PRESENT DISCLOSURE

In the present disclosure, an organic light emitting element includes a substrate, a first electrode, a second electrode, a first organic light emitting layer and a second organic light emitting layer. The first electrode and the second electrode are over the substrate. The first organic light emitting layer is over the first electrode. The second organic light emitting layer is over the second electrode. A difference between a thickness of the second organic light emitting layer and a thickness of the first organic light emitting layer is greater than 500 angstrom (Å) and less than 1500 Å.

In the present disclosure, a manufacturing method of an organic light emitting element includes: providing a substrate; disposing a first electrode and a second electrode over the substrate; forming a first organic light emitting layer over the first electrode; and forming a second organic light emitting layer over the second electrode to generate a difference between a thickness of the second organic light emitting layer and a thickness of the first organic light emitting layer that is greater than 500 Å and less than 1500 Å.

In some embodiments, the organic light emitting element further includes a third electrode and a third organic light emitting layer. The third electrode is over the substrate. The third organic light emitting layer is over the third electrode. A difference between the thickness of the second organic light emitting layer and a thickness of the third organic light emitting layer is greater than 800 angstrom Å and less than 1800 Å.

In some embodiments, a luminescence wavelength of the second organic light emitting layer is greater than a luminescence wavelength of the first organic light emitting layer, and the luminescence wavelength of the first organic light emitting layer is greater than a luminescence wavelength of the third organic light emitting layer.

In some embodiments, the thickness of the second organic light emitting layer is greater than the thickness of the first organic light emitting layer, and the thickness of the first organic light emitting layer is greater than the thickness of the third organic light emitting layer.

In some embodiments, the first organic light emitting layer includes a first hole transport layer, the second organic light emitting layer includes a second hole transport layer, and the third organic light emitting layer includes a third hole transport layer, a thickness of the second hole transport layer is greater than a thickness of the first hole transport layer, and the thickness of the first hole transport layer is greater than a thickness of the third hole transport layer.

In some embodiments, the first organic light emitting layer includes a first electron transport layer, the second organic light emitting layer includes a second electron transport layer, the third organic light emitting layer includes a third electron transport layer, and a thickness of the second electron transport layer is greater than a thickness of the first electron transport layer and a thickness of the third electron transport layer.

In some embodiments, the first organic light emitting layer includes a first hole transport layer, the second organic light emitting layer includes a second hole transport layer, and a difference between a thickness of the second hole transport layer and a thickness of the first hole transport layer is greater than 300 angstrom Å and less than 1000 Å.

In some embodiments, the first organic light emitting layer includes a first hole transport layer, the second organic light emitting layer includes a second hole transport layer, and an elevation of an upper surface of the second hole transport layer is higher than an elevation of an upper surface of the first hole transport layer.

In some embodiments, the organic light emitting element further includes a spacer structure, which is disposed over the substrate and between the first organic light emitting layer and the second organic light emitting layer, wherein a vertical distance between the elevation of the upper surface of the second hole transport layer and an elevation of an upper surface of the spacer structure is less than a vertical distance between the elevation of the upper surface of the first hole transport layer and the elevation of the upper surface of the spacer structure.

In some embodiments, the organic light emitting element further includes a spacer structure, which is disposed over the substrate and partially covers the first electrode, wherein a first edge of the second hole transport layer and a second edge opposite to the first edge are above the spacer structure and are at different elevations.

In some embodiments, the organic light emitting element further includes a spacer structure, which is disposed over the substrate and between the first organic light emitting layer and the second organic light emitting layer, wherein the first hole transport layer and the second hole transport layer partially cover the spacer structure, and an extension length of the second hole transport layer on the spacer structure is greater than an extension length of the first hole transport layer on the spacer structure.

In some embodiments, the organic light emitting element further includes a third electrode and a third organic light emitting layer. The third electrode is over the substrate. The third organic light emitting layer is over the third electrode and includes a third hole transport layer, wherein the elevation of the upper surface of the second hole transport layer is higher than an elevation of an upper surface of the third hole transport layer.

In some embodiments, the difference between the thickness of the second organic light emitting layer and the thickness of the first organic light emitting layer is greater than 700 Å and less than 1500 Å.

In some embodiments, the difference between the thickness of the second organic light emitting layer and the thickness of the first organic light emitting layer is greater than 700 Å and less than 1000 Å.

In some embodiments, the first organic light emitting layer includes an electron transport layer and a hole injection layer. The electron transport layer includes an organic barrier material, and the hole injection layer includes a transition metal oxide.

In some embodiments, the organic light emitting element further includes a top electrode, an inorganic barrier layer and a capping layer. The top electrode is over the first organic light emitting layer, the inorganic barrier layer covers the top electrode, and the capping layer is over the inorganic barrier layer and is separated from the top electrode by the inorganic barrier layer.

In some embodiments, the manufacturing method of an organic light emitting element further includes: forming a spacer structure over the substrate to partially cover the first electrode, wherein the first organic light emitting layer and the second organic light emitting layer partially cover the spacer structure; and forming a top electrode layer over the spacer structure, the first organic light emitting layer and the second organic light emitting layer.

In some embodiments, forming the first organic light emitting layer includes forming a first hole transport layer over the first electrode; and forming the second organic light emitting layer includes forming a second hole transport layer over the second electrode to generate a difference between a thickness of the second hole transport layer and a thickness of the first hole transport layer that is greater than 300 Å and less than 1000 Å.

In some embodiments, forming the first organic light emitting layer includes forming a first hole transport layer over the first electrode, and forming a first organic emission layer over the first hole transport layer; and forming the second organic light emitting layer includes forming a second hole transport layer over the second electrode, and forming the second organic emission layer over the second hole transport layer to generate a difference between a thickness of the second hole transport layer and a thickness of the first hole transport layer that is greater than a difference between the thickness of the second organic emission layer and the thickness of the first organic emission layer.

### BRIEF DESCRIPTION OF THE DRAWINGS

FIG. 1 is a top view of an exemplary intermediate product of an organic light emitting element.

FIG. 2 is a cross-sectional diagram taken along the line A-A′ in FIG. 1.

FIG. 2A is a cross-sectional diagram of the organic light emitting unit in FIG. 2.

FIG. 2B is a cross-sectional diagram of the organic light emitting unit in FIG. 2.

FIG. 2C is a cross-sectional diagram of the organic light emitting unit in FIG. 2.

FIG. 3A to FIG. 3R depict a manufacturing method of an organic light emitting element according to some embodiments.

FIG. 4 is a cross-sectional diagram taken along the line A-A′ in FIG. 1.

FIG. 4A is a cross-sectional diagram of the organic light emitting unit in FIG. 4.

FIG. 4B is a cross-sectional diagram of the organic light emitting unit in FIG. 4.

FIG. 4C is a cross-sectional diagram of the organic light emitting unit in FIG. 4.

### DETAILED DESCRIPTION OF THE EMBODIMENTS

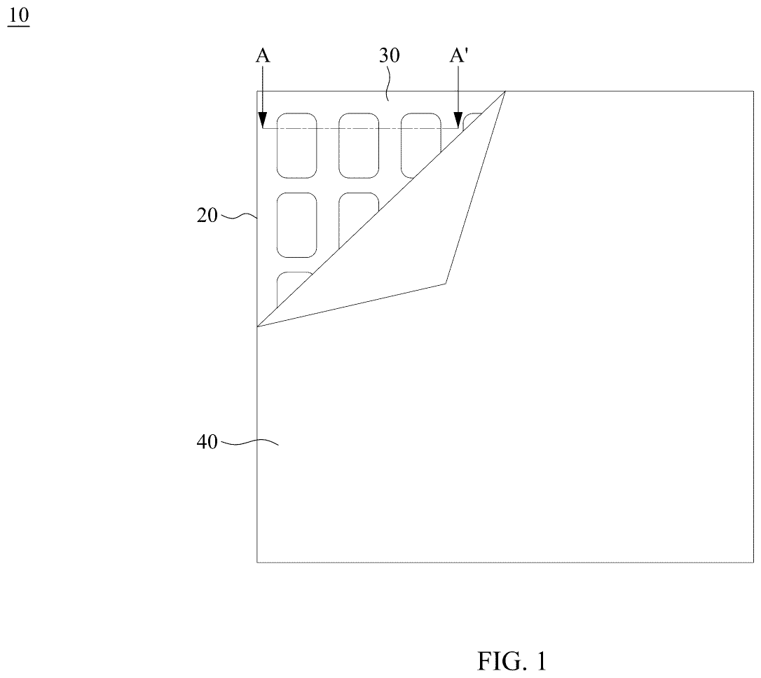

FIG. 1 shows a top view of an exemplary intermediate product of an organic light emitting element 10. The light emitting element 10 includes a light emitting layer 20 and a cover layer 40 over the light emitting layer 20. For the light emitting layer 20, a spacer structure 30 may be designed to provide a recess array used to accommodate a light emitting pixel array. In some embodiments, the spacer structure 30 may include a protrusion 310. In some embodiments, the spacer structure 30 may include a photosensitive material.

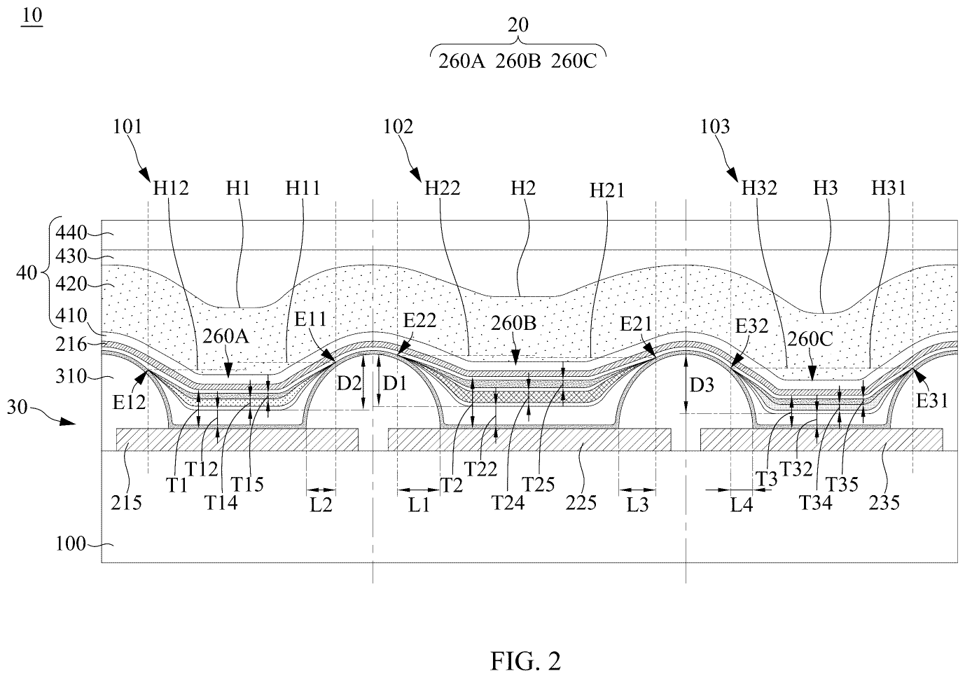

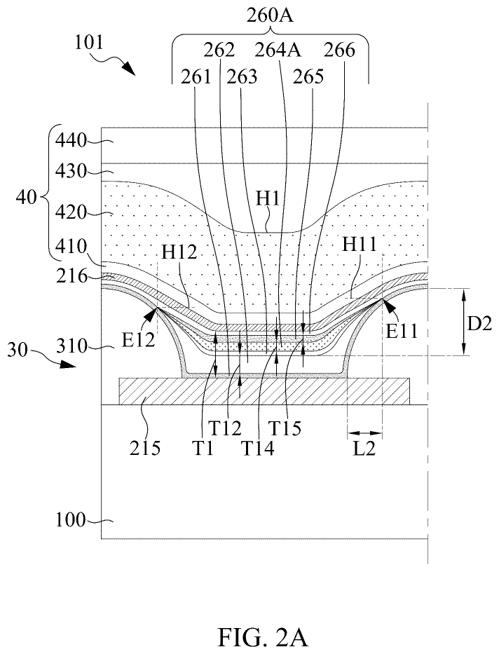

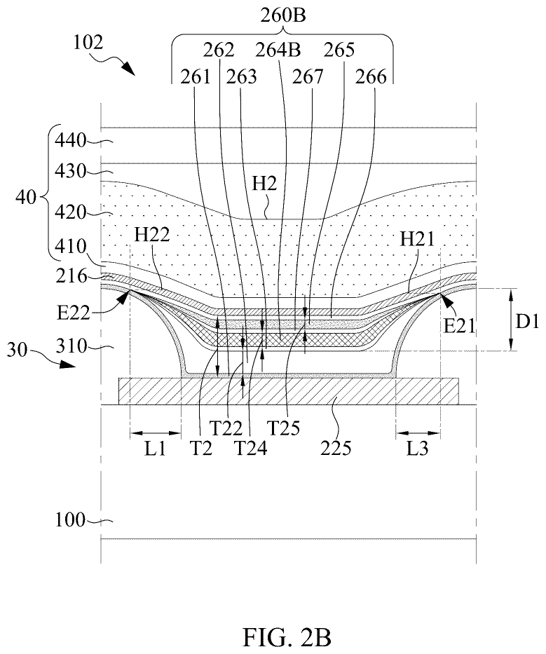

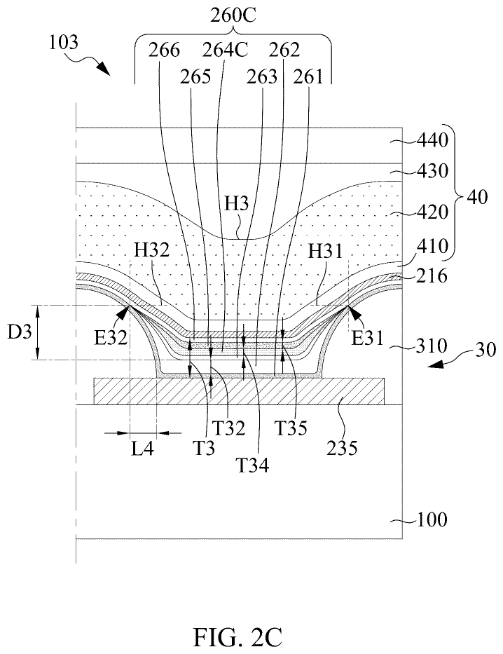

FIG. 2 shows a cross-sectional diagram taken along the line A-A′ in FIG. 1. FIG. 2A shows a cross-sectional diagram of an organic light emitting unit 101 in FIG. 2. FIG. 2B shows a cross-sectional diagram of an organic light emitting unit 102 in FIG. 2. FIG. 2C shows a cross-sectional diagram of an organic light emitting unit 103 in FIG. 2. In some embodiments, FIG. 2 shows a cross-sectional diagram taken along the line A-A′ in FIG. 1 as an example, and only a light emitting region is illustrated. The spacer structure 30 includes a plurality of protrusions 310 to define a light emitting pixel pattern. A recess is between two adjacent protrusions 310 and provides a space for accommodating light emitting pixels. When viewing the cross-sectional diagrams shown in FIG. 2, FIG. 2A, FIG. 2B and FIG. 2C, a person skilled in the art would be able to understand that the protrusions 310 are depicted in a disconnected manner. However, when viewing the schematic top view of FIG. 1, the protrusions 310 can be connected to one another by other parts of the spacer structure 30.

As shown in FIG. 2, in some embodiments, the organic light emitting element 10 is, for example, a light emitting element including an organic light emitting diode (OLED) structure. In some embodiments, the light emitting element 10 includes a plurality of organic light emitting units (or referred to as light emitting pixels), for example, including at least an organic light emitting unit 101 (or referred to as a first organic light emitting unit), an organic light emitting unit 102 (or referred to as a second organic light emitting unit), and an organic light emitting unit 103 (or referred to as a third organic light emitting unit). In some embodiments, the organic light emitting units 101, 102 and 103 are between the protrusions 310 and above the substrate 100. The organic light emitting units 101, 102 and 103 may emit light having the same wavelength or light having different wavelengths.

In some embodiments, the organic light emitting element 10 includes a substrate 100, an electrode 215 (or referred to as a first electrode), an electrode 225 (or referred to as a second electrode), an electrode 235 (or referred to as a third electrode), an electrode 216 (or referred to as a top electrode or a common electrode), the light emitting layer 20, the spacer structure 30 and the cover layer 40.

In some embodiments, the substrate 100 may include a transistor array, which is configured to correspond to light emitting pixels in the light emitting layer 20. The substrate 100 may include a plurality of capacitors. In some embodiments, more than one transistor is configured with one capacitor and one light emitting pixel to form a circuit. In some embodiments, the substrate 100 may include glass.

In some embodiments, the electrodes 215, the electrode 225 and the electrode 235 are on the substrate 100. In some embodiments, the electrode 215, 225 and 235 are anodes. In some embodiments, the electrodes 215, 225 and 235 include a metal material, for example, Ag, Al, Mg, Au, AlCu alloy or AgMo alloy. In some embodiments, the electrodes 215, 225 and 235 include indium tin oxide (ITO), indium zinc oxide (IZO) or other appropriate materials.

In some embodiments, the light emitting layer 20 includes an organic light emitting layer 260A (or referred to as a first organic light emitting layer), an organic light emitting layer 260B (or referred to as a second organic light emitting layer) and an organic light emitting layer 260C (or referred to as a third organic light emitting layer). In some embodiments, the organic light emitting layer 260A is over the electrode 215, the organic light emitting layer 260B is over the electrode 225, and the organic light emitting layer 260C is over the electrode 235.

In some embodiments, a thickness T1 of the organic light emitting layer 260A, a thickness T2 of the organic light emitting layer 260B and a thickness T3 of the organic light emitting layer 260C are different from one another. A difference between the thickness T2 of the organic light emitting layer 260B and the thickness T1 of the organic light emitting layer 260A is greater than 500 angstrom (Å) and less than 1500 Å, greater than 700 Å and less than 1500 Å, greater than 600 Å and less than 1300 Å, or greater than 700 Å and less than 1000 Å. A difference between the thickness T2 of the organic light emitting layer 260B and the thickness T3 of the organic light emitting layer 260C is greater than 800 Å and less than 1800 Å, greater than 900 Å and less than 1600 Å, or greater than 1000 Å and less than 1400 Å. In some embodiments, the thickness T2 of the organic light emitting layer 260B is greater than the thickness T1 of the organic light emitting layer 260A, and the thickness T1 of the organic light emitting layer 260A is greater than the thickness T3 of the organic light emitting layer 260C.

In some embodiments, when the difference between the thickness T2 of the organic light emitting layer 260B and the thickness T1 of the organic light emitting layer 260A is greater than 1500 Å, the organic light emitting layer 260B protrudes from an upper surface of the entire light emitting layer 20, such that an encapsulation layer 420 above the organic light emitting layer 260B may impose a relatively large stress upon a partial region above the organic light emitting layer 260B, and hence the electrode 216 over the organic light emitting layer 260B is susceptible to disconnection due to the stress brought upon by pressing between the encapsulation layer 420 and the organic light emitting layer 260B. In some embodiments, when a luminescence wavelength of the organic light emitting layer 260B is greater than a luminescence wavelength of the organic light emitting layer 260A and the difference between the thickness T2 of the organic light emitting layer 260B and the thickness T1 of the organic light emitting layer 260A is less than 500 Å, the thickness T2 of the organic light emitting layer 260B or the thickness T1 of the organic light emitting layer 260A may fail to provide a good microcavity structure, rendering light emitting luminance or chrominance of an organic light emitting component to be less than expected.

According to some embodiments of the present disclosure, the difference between the thickness T2 of the organic light emitting layer 260B and the thickness T1 of the organic light emitting layer 260A is especially designed to be greater than 500 Å and less than 1500 Å, greater than 700 Å and less than 1500 Å, greater than 600 Å and less than 1300 Å, or greater than 700 Å and less than 1000 Å. Thus, in addition to providing the organic light emitting element 10 with good luminance and extremely small color shift in CIE 1931 coordinates, the electrode 216 can be effectively prevented from disconnection caused by pressing and stress, thereby improving reliability of components.

In some embodiments, an elevation of an upper surface of the organic light emitting layer 260B is higher than an elevation of an upper surface of the organic light emitting layer 260A. In some embodiments, a difference between the elevation of the upper surface of the organic light emitting layer 260B and the elevation of the upper surface of the organic light emitting layer 260A is greater than 500 Å and less than 1500 Å, greater than 700 Å and less than 1500 Å, greater than 600 Å and less than 1300 Å, or greater than 700 Å and less than 1000 Å. In some embodiments, the elevation of the upper surface of the organic light emitting layer 260A is higher than an elevation of an upper surface of the organic light emitting layer 260C.

According to some embodiments of the present disclosure, the difference between the elevation of the upper surface of the organic light emitting layer 260B and the elevation of the upper surface of the organic light emitting layer 260A is especially designed to be greater than 500 Å and less than 1500 Å, greater than 700 Å and less than 1500 Å, greater than 600 Å and less than 1300 Å, or greater than 700 Å and less than 1000 Å, such that the organic light emitting layer 260B does not overly protrude from the upper surface of the entire light emitting layer 20, thereby reducing the stress brought by the encapsulation layer 420 above the organic light emitting layer 260B upon the partial region above the organic light emitting layer 260B and hence effectively preventing the electrode 216 over the organic light emitting layer 260B from disconnection owing to the stress brought upon by pressing between the encapsulation layer 420 and the organic light emitting layer 260B.

In some embodiments, the organic light emitting layers 260A, 260B and 260C emit light in the same color or different colors. In some embodiments, the luminescence wavelength of the organic light emitting layer 260B is greater than the luminescence wavelength of the organic light emitting layer 260A, and the luminescence wavelength of the organic light emitting layer 260A is greater than the luminescence wavelength of the organic light emitting layer 260C. In some embodiments, the organic light emitting layer 260A emits green light, the organic light emitting layer 260B emits red light, and the organic light emitting layer 260C emits blue light.

In some embodiments, the organic material layers of the organic light emitting layers 260A, 260B and 260C include an organic material, which may be placed in any one of the organic material layers of the organic light emitting layers 260A, 260B and 260C according to different embodiments. In some embodiments, the organic material has an absorption rate of greater than or equal to 50% for a specific wavelength. In some embodiments, the organic material has an absorption rate of greater than or equal to 60% for a specific wavelength. In some embodiments, the organic material has an absorption rate of greater than or equal to 70% for a specific wavelength. In some embodiments, the organic material has an absorption rate of greater than or equal to 80% for a specific wavelength. In some embodiments, the organic material has an absorption rate of greater than or equal to 90% for a specific wavelength. In some embodiments, the organic material has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, the organic light emitting unit 101 includes the electrode 215 (or referred to as the first electrode), the organic light emitting layer 260A, and the electrode 216 (or referred to as the top electrode or the common electrode). In some embodiments, the organic light emitting layer 260A includes multiple organic material layers, for example, a hole injection layer (HIL) 261, a hole transport layer (HTL) 262 (or referred to as a first hole transport layer), an electron barrier layer (EBL) 263, an organic emission layer (EML) 264A (or referred to as a first organic emission layer), an electron transport layer (ETL) 265 (or referred to as a first electron transport layer), and an electron injection layer (EIL) 266. In some embodiments, the electrode 216 is over the organic light emitting layer 260A.

As shown in FIG. 2B, in some embodiments, the organic light emitting unit 102 includes the electrode 225 (or referred to as the second electrode), the organic light emitting layer 260B, and the electrode 216 (or referred to as the top electrode or the common electrode). In some embodiments, the organic light emitting layer 260B includes multiple organic material layers, for example, a hole injection layer (HIL) 261, a hole transport layer (HTL) 262 (or referred to as a second hole transport layer), an electron barrier layer (EBL) 263, an organic emission layer (EML) 264B (or referred to as a second organic emission layer), a hole barrier layer (HBL) 267, an electron transport layer (ETL) 265 (or referred to as a second electron transport layer), and an electron injection layer (EIL) 266. In some embodiments, the electrode 216 is over the organic light emitting layer 260B.

As shown in FIG. 2C, in some embodiments, the organic light emitting unit 103 includes the electrode 235 (or referred to as the third electrode), the organic light emitting layer 260B, and the electrode 216 (or referred to as the top electrode or the common electrode). In some embodiments, the organic light emitting layer 260C includes multiple organic material layers, for example, a hole injection layer (HIL) 261, a hole transport layer (HTL) 262 (or referred to as a third hole transport layer), an electron barrier layer (EBL) 263, an organic emission layer (EML) 264C (or referred to as a third organic emission layer), an electron transport layer (ETL) 265 (or referred to as a third electron transport layer), and an electron injection layer (EIL) 266. In some embodiments, the electrode 216 is over the organic light emitting layer 260C.

In some embodiments, an edge E11 of the hole transport layer 262 of the organic light emitting layer 260A and an edge E12 opposite to the edge E11 are above the spacer structure 30 and are at different elevations. The edge E11 is at an elevation H11, and the edge E12 is at an elevation H12. In some embodiments, an edge E21 of the hole transport layer 262 of the organic light emitting layer 260B and an edge E22 opposite to the edge E21 are above the spacer structure 30 and are at different elevations. The edge E21 is at an elevation H21, and the edge E22 is at an elevation H22. In some embodiments, an edge E31 of the hole transport layer 262 of the organic light emitting layer 260C and an edge E32 opposite to the edge E31 are above the spacer structure 30 and are at substantially the same elevation. The edge E31 is at an elevation H31, and the edge E32 is at an elevation H32.

In some embodiments, the edge E11 of the hole transport layer 262 of the organic light emitting layer 260A is closer to the organic light emitting layer 260B than the edge E12, and the elevation H11 of the edge E11 is higher than the elevation H12 of the edge E12.

According to some embodiments of the present disclosure, by configuring the elevation H11 of the edge E11 to be higher than the elevation H12 of the edge E12, a step difference between the organic light emitting layer 260B and the protrusion 310 and a step difference between the protrusion 310 and the organic light emitting layer 260A can be reduced, such an entire upper surface of the organic light emitting layer 260B extending to the organic light emitting layer 260A via the protrusion 310 appears more moderate to further alleviate a level of bulging of the protrusion 310, and as a result, the protrusion 310 does not overly protrude from the upper surface of the entire light emitting layer 20. Thus, the stress brought by the encapsulation layer 420 above the protrusion 310 upon the partial region over the protrusion 310 can be reduced, thereby effectively preventing the electrode 216 over the protrusion 310 from disconnection owing to the stress brought upon by pressing between the encapsulation layer 420 and the protrusion 310.

In some embodiments, all of the hole transport layer 262 of the organic light emitting layer 260A, the hole transport layer 262 of the organic light emitting layer 260B and the hole transport layer 262 of the organic light emitting layer 260C partially cover the spacer structure 30. In some embodiments, an extension length L1 of the hole transport layer 262 of the organic light emitting layer 260B on the spacer structure 30 is greater than an extension length L2 of the hole transport layer 262 of the organic light emitting layer 260A on the spacer structure 30. In some embodiments, an extension length L3 of the hole transport layer 262 of the organic light emitting layer 260B is greater than an extension length LA of the hole transport layer 262 of the organic light emitting layer 260C on the spacer structure 30.

In some embodiments, a thickness T22 of the hole transport layer 262 of the organic light emitting layer 260B is greater than a thickness T12 of the hole transport layer 262 of the organic light emitting layer 260A, and the thickness T12 of the hole transport layer 262 of the organic light emitting layer 260A is greater than a thickness T32 of the hole transport layer 262 of the organic light emitting layer 260C. In some embodiments, a difference between the thickness T22 of the hole transport layer 262 of the organic light emitting layer 260B and the thickness T12 of the hole transport layer 262 of the organic light emitting layer 260A is greater than 300 Å and less than 1000 Å, greater than 350 Å and less than 800 Å, or greater than 400 Å and less than 600 Å. In some embodiments, a difference between the thickness T22 of the hole transport layer 262 of the organic light emitting layer 260B and the thickness T32 of the hole transport layer 262 of the organic light emitting layer 260C is greater than 500 Å and less than 1500 Å, greater than 600 Å and less than 1300 Å, or greater than 700 Å and less than 1200 Å.

In some embodiments, an elevation of an upper surface of the hole transport layer 262 the organic light emitting layer 260B is higher than an elevation of an upper surface of the hole transport layer 262 of the organic light emitting layer 260A. In some embodiments, the elevation of the upper surface of the hole transport layer 262 the organic light emitting layer 260B is higher than an elevation of an upper surface of the hole transport layer 262 of the organic light emitting layer 260C.

In some embodiments, a thickness T24 of the organic emission layer 264B is greater than a thickness T14 of the organic emission layer 264A, and the thickness T14 of the organic emission layer 264A is greater than a thickness T34 of the organic emission layer 264C. In some embodiments, a difference between the thickness T24 of the organic emission layer 264B and the thickness T14 of the organic emission layer 264A is greater than 50 Å and less than 400 Å, greater than 80 Å and less than 300 Å, or greater than 100 Å and less than 200 Å. In some embodiments, a difference between the thickness T24 of the organic emission layer 264B and the thickness T34 of the organic emission layer 264C is greater than 80 Å and less than 600 Å, greater than 100 Å and less than 500 Å, or greater than 150 Å and less than 300 Å.

In some embodiments, a thickness T25 of the electron transport layer 265 of the organic light emitting layer 260B is greater than a thickness T15 of the electron transport layer 265 of the organic light emitting layer 260A and greater than a thickness T35 of the electron transport layer 265 of the organic light emitting layer 260C. In some embodiments, a difference between the thickness T25 of the electron transport layer 265 of the organic light emitting layer 260B and the thickness T15 of the electron transport layer 265 of the organic light emitting layer 260A is greater than 50 Å and less than 300 Å, greater than 70 Å and less than 200 Å, or greater than 90 Å and less than 150 Å. In some embodiments, a difference between the thickness T25 of the electron transport layer 265 of the organic light emitting layer 260B and the thickness T35 of the electron transport layer 265 of the organic light emitting layer 260C is greater than 50 Å and less than 300 Å, greater than 70 Å and less than 200 Å, or greater than 90 Å and less than 150 Å.

In some embodiments, by adjusting the thickness of the hole transport layer 262, the thicknesses of the organic emission layers 264A, 264B and 264C and the thickness of the electron transport layer 265, adjustment can be made to obtain predetermined thickness differences of the organic light emitting layers 260A, 260B and 260C, thereby achieving a technical effect of preventing the electrode 216 from disconnection owing to the stress brought upon by pressing between the encapsulation layer 420 and the light emitting layer 20. According to some embodiments of the present disclosure, the predetermined thickness differences of the organic light emitting layers 260A, 260B and 260C may be adjusted and obtained primarily by adjusting the thickness of the hole transport layer 262. Thus, influences of the thicknesses of the organic light emitting layers 260A, 260B and 260C upon light emitting performance of the organic light emitting element 10 can be further reduced, the electrode can be prevented from disconnection, and the technical effect of maintaining good light emitting performance can also be achieved.

In some embodiments, the electrode 216 contacts the organic light emitting layers 260A, 260B and 260C. The electrode 216 may be a continuous film as shown in FIG. 2 and over the organic light emitting layers 260A, 260B and 260C and the protrusions 310. In some embodiments, the electrode 216 may be further over the spacer structure 30. In some embodiments, the electrode 216 is a common electrode of all light emitting pixels in the light emitting layer 20. In some embodiments, the electrode 216 includes a metal material, for example, Ag, Al, Mg, Au, AlCu alloy or AgMo alloy. In some embodiments, the electrode 216 includes ITO, IZO or other appropriate materials. In other words, the electrode 216 is a common electrode of a plurality of organic light emitting units. In some embodiments, the electrode 216 is a common electrode of all organic light emitting units in the organic light emitting element 10.

In some embodiments, the spacer structure 30 is on the substrate 100 and partially covers the electrodes 215, 225 and 235. In some embodiments, the spacer structure 30 is located among the organic light emitting layers 260A, 260B and 260C. In some embodiments, the spacer structure 30 may include the protrusions 310. In some embodiments, a pattern of the spacer structure 30 is designed according to a pixel layout. In some embodiments, the spacer structure 30 serves as a pixel defined layer (PDL). In some embodiments, the protrusions 310 define a pixel region. In some embodiments, each protrusion 310 fills a gap between two adjacent ones of the electrodes 215, 225 and 235. Each of the electrodes 215, 225 and 235 is partially covered by the protrusion 310. In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a black body material, which has an absorption rate of more than 90%, 95%, 99%, 99.5% 99.9% for visible light.

In some embodiments, the spacer structure 30 has an absorption rate of greater than or equal to 50% for a specific wavelength. In some embodiments, the spacer structure 30 has an absorption rate of greater than or equal to 60% for a specific wavelength. In some embodiments, the spacer structure 30 has an absorption rate of greater than or equal to 70% for a specific wavelength. In some embodiments, the spacer structure 30 has an absorption rate of greater than or equal to 80% for a specific wavelength. In some embodiments, the spacer structure 30 has an absorption rate of greater than or equal to 90% for a specific wavelength. In some embodiments, the spacer structure 30 has an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, a vertical distance D1 between the elevation of the upper surface of the hole transport layer 262 of the organic light emitting layer 260B and an elevation of an upper surface of the spacer structure 30 is less than a vertical distance D2 between the elevation of the upper surface of the hole transport layer 262 of the organic light emitting layer 260A and the elevation of the upper surface of the spacer structure 30. In some embodiments, the vertical distance D2 between the elevation of the upper surface of the hole transport layer 262 of the organic light emitting layer 260A and the elevation of the upper surface of the spacer structure 30 is less than a vertical distance D3 between the elevation of the upper surface of the hole transport layer 262 of the organic light emitting layer 260C and the elevation of the upper surface of the spacer structure 30.

In some embodiments, the cover layer 40 includes a capping layer 410, the encapsulation layer 420, a filler layer 430 and a cover plate 440. In some embodiments, the capping layer 410 is disposed on the electrode 216, and is substantially conformal with a non-flat upper surface of the electrode 216. The capping layer 410 may include a dielectric material or an inorganic insulating material, for example, SiO₂. In some embodiments, the capping layer 410 may include a hole transport layer material to extract light lost inside the organic light emitting element so as to improve light emitting efficiency. The capping layer 410 may also be referred to as a light extraction layer.

In some embodiments, the encapsulation layer 420 is disposed on the capping layer 410, and is substantially conformal with a non-flat upper surface of the capping layer 410. The encapsulation layer 420 may include an oxide, for example, SiO₂. In some embodiments, the encapsulation layer 420 is substantially conformal with the non-flat upper surface of the capping layer 410, and includes a plurality of recesses corresponding to the organic light emitting layers 260A, 260B and 260C. In some embodiments, the plurality of recesses of the encapsulation layer 420 are at different elevations H1, H2 and H3. In some embodiments, the elevation H2 is higher than the elevation H1, and the elevation H1 is higher than the elevation H3. In some embodiments, a vertical distance between the elevation H2 and the elevation H1 is greater than 500 Å and less than 1500 Å, greater than 700 Å and less than 1500 Å, greater than 600 Å and less than 1300 Å, or greater than 700 Å and less than 1000 Å. In some embodiments, a vertical distance between the elevation H2 and the elevation H3 is greater than 800 Å and less than 1800 Å, greater than 900 Å and less than 1600 Å, or greater than 1000 Å and less than 1400 Å. The encapsulation layer 420 may include a polymer organic material, for example, an epoxy-based material.

In some embodiments, the filler layer 430 is disposed on the encapsulation layer 420, and a lower surface of the filler layer 430 is substantially conformal with a non-flat upper surface of the encapsulation layer 420. The filler layer 430 may also be referred to as a flat layer. The filler layer 430 may include a polymer organic material, for example, an epoxy-based material.

In some embodiments, the cover plate 440 is disposed on a flat upper surface of the filler layer 430. The cover plate 440 may also be referred to as a protective layer. The cover plate 440 may include a transparent hard cover plate, for example, a glass plate. The cover plate 440 may be used to prevent components of the organic light emitting element from coming into contact with external moisture and hence from malfunction and light emission failures of the components.

In the technical field of organic light emitting elements, a person of ordinary skill in the art commonly tends to consider that, according to simulation results of a microcavity, optimal luminous performance can be achieved if different organic light emitting layers are individually designed to have a total thickness that is one-half of a wavelength of the emitted light. For example, the thickness of a red organic light emitting layer is designed to be 3125 Å (one-half of 625 nm), the thickness of a green organic light emitting layer is designed to be 2600 Å (one-half of 520 nm), and the thickness of a blue organic light emitting layer is designed to be 2350 Å (one-half of 470 nm). However, when the thickness of the red organic light emitting layer is overly large, that is, when the red organic light emitting layer protrudes from the upper surface of the entire organic light emitting layer, the encapsulation layer 420 above the organic light emitting layer may impose a relatively large stress upon a partial region above the red organic emitting layer, and hence the electrode 216 over the red organic light emitting layer is susceptible to disconnection due to the stress brought upon by pressing between the encapsulation layer 420 and the red organic light emitting layer.

According to some embodiments of the present disclosure, the difference between the thickness T2 of the organic light emitting layer 260B and the thickness T1 of the organic light emitting layer 260A is especially designed to be greater than 500 Å and less than 1500 Å. Thus, in addition to providing the organic light emitting element 10 with good luminance and extremely small color shift in CIE 1931 coordinates, the electrode 216 can be effectively prevented from disconnection caused by pressing and stress, thereby improving reliability of components.

In addition, according to some embodiments of the present disclosure, the difference between the elevation of the upper surface of the organic light emitting layer 260B and the elevation of the upper surface of the organic light emitting layer 260A is especially designed to be greater than 500 Å and less than 1500 Å, greater than 700 Å and less than 1500 Å, greater than 600 Å and less than 1300 Å, or greater than 700 Å and less than 1000 Å. Thus, the level of bulging of the upper surface of the organic light emitting layer 260B can be reduced, so that the electrode 216 is effectively prevented from disconnection caused by pressing and stress, thereby improving reliability of components.

Moreover, according to some embodiments of the present disclosure, the difference in elevations or the difference in thicknesses above is not only within a numerical range that can be obtained from a limited range, but a breakthrough over intrinsic technical thinking that thicknesses of organic light emitting layers emitting light in different colors are fixedly designed in the art is made. Accordingly, relationships of thicknesses or relationships of elevations among organic light emitting layers emitting light in different colors are especially designed, so as to achieve optimal luminance and minimal color shift as well as unexpected technical results of good reliability and yield.

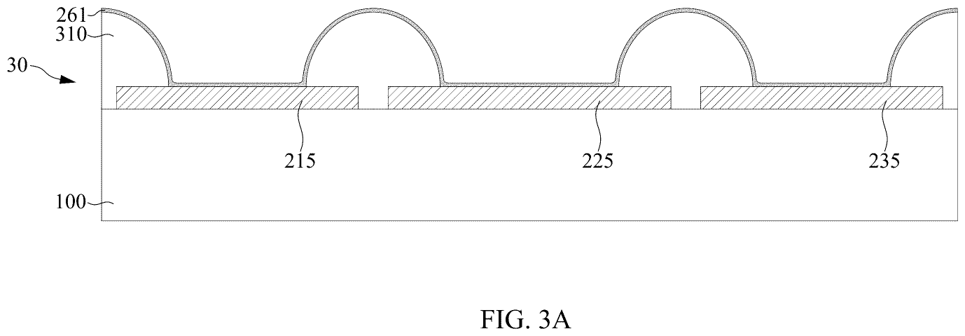

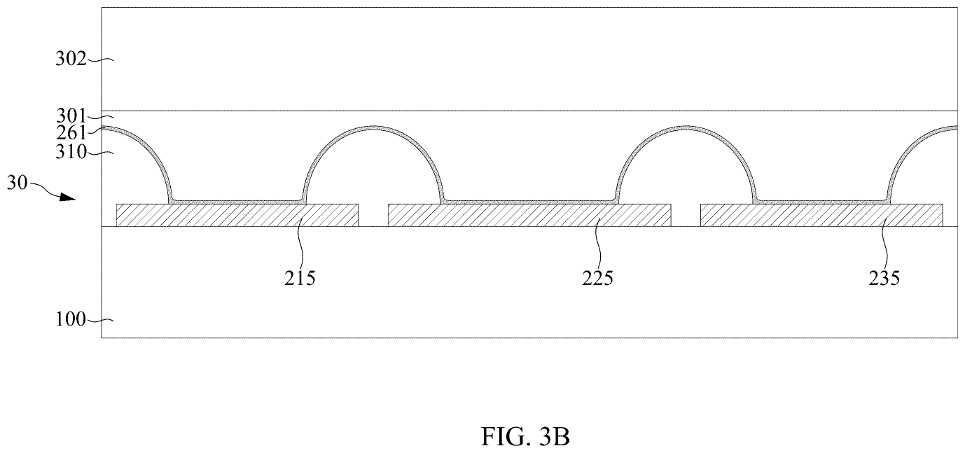

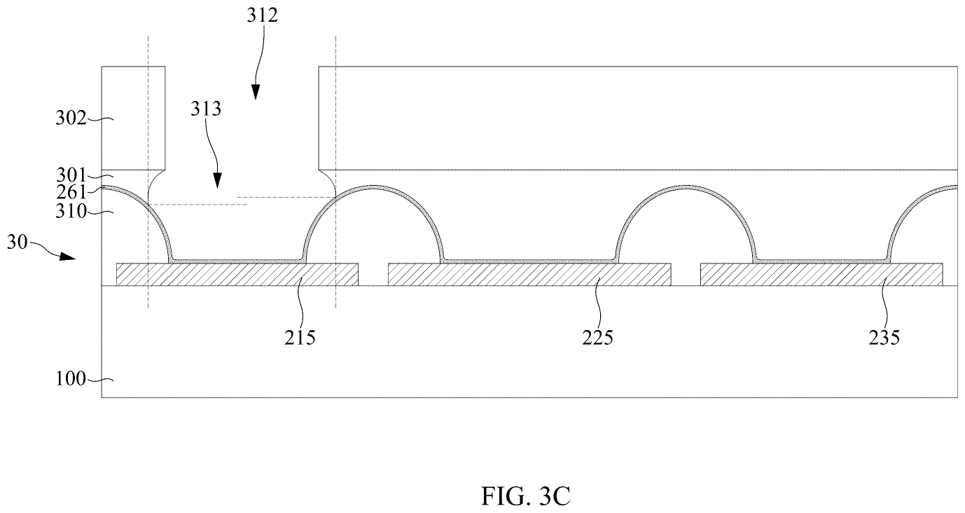

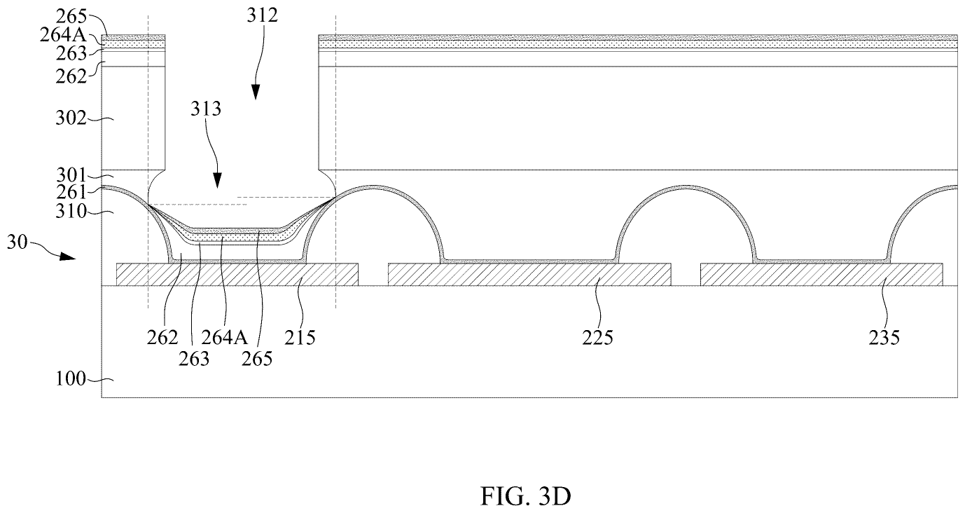

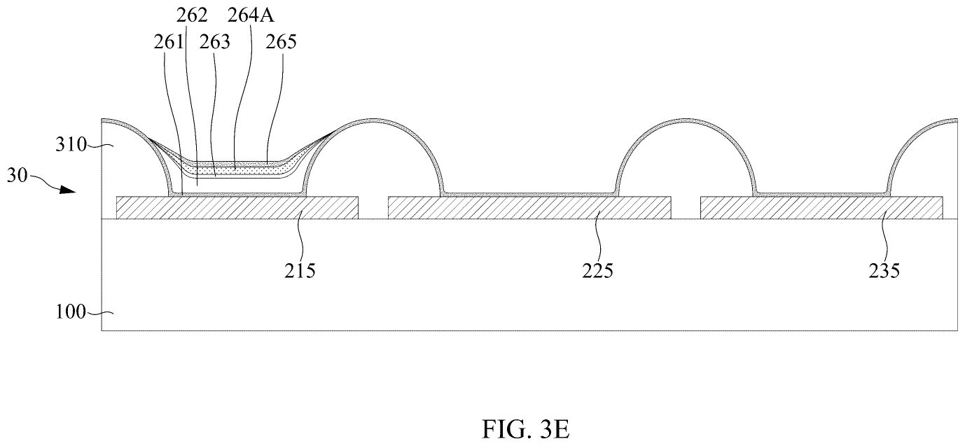

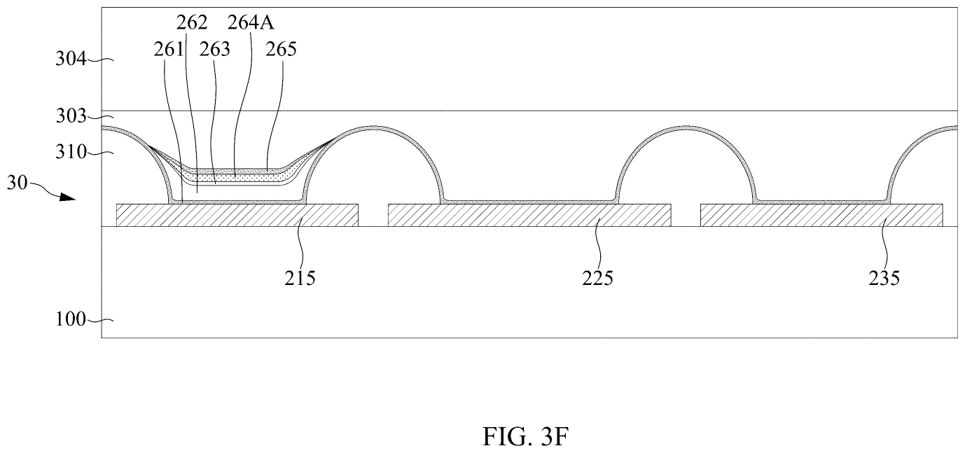

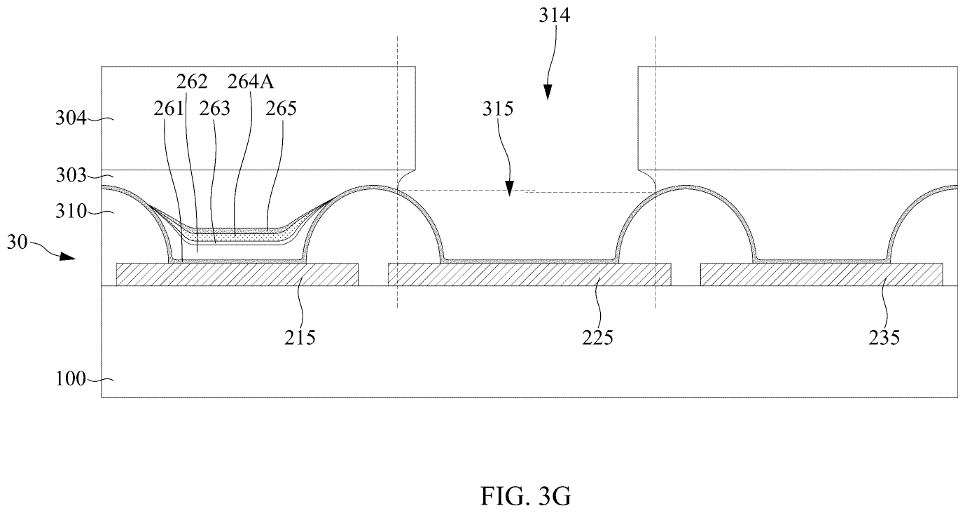

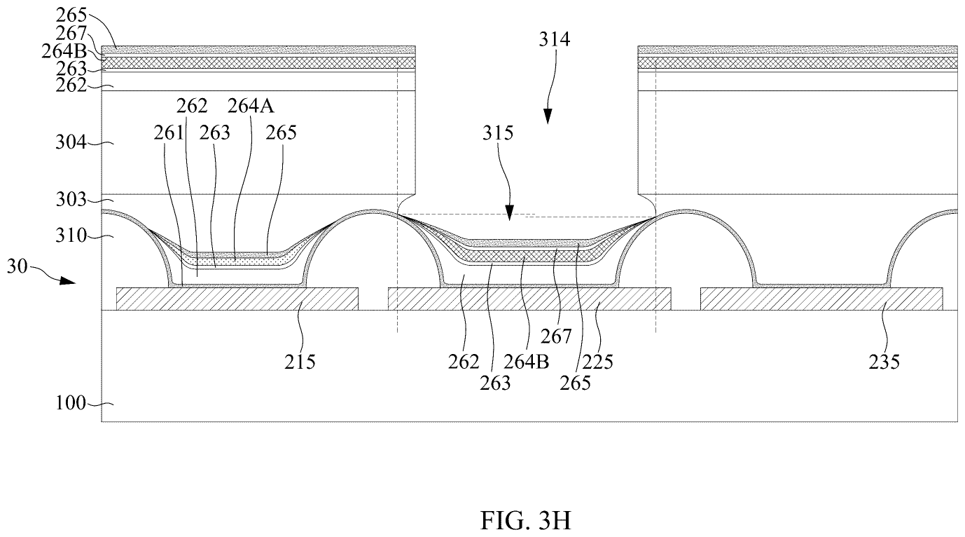

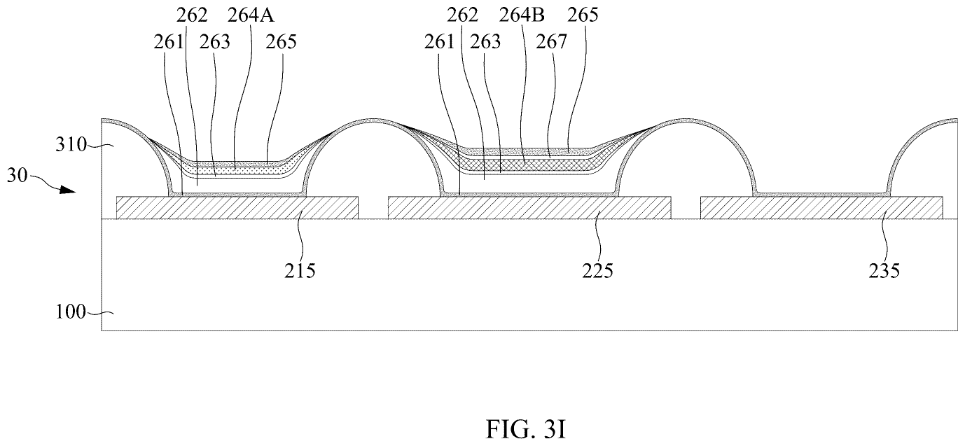

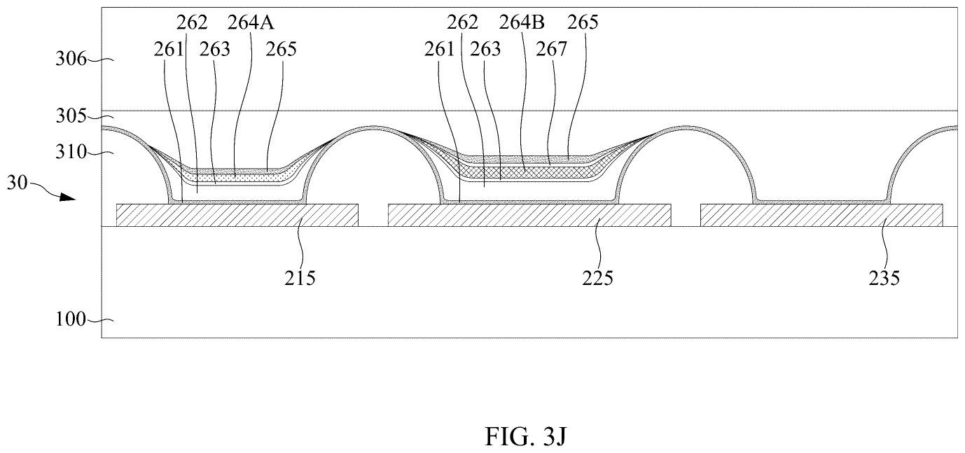

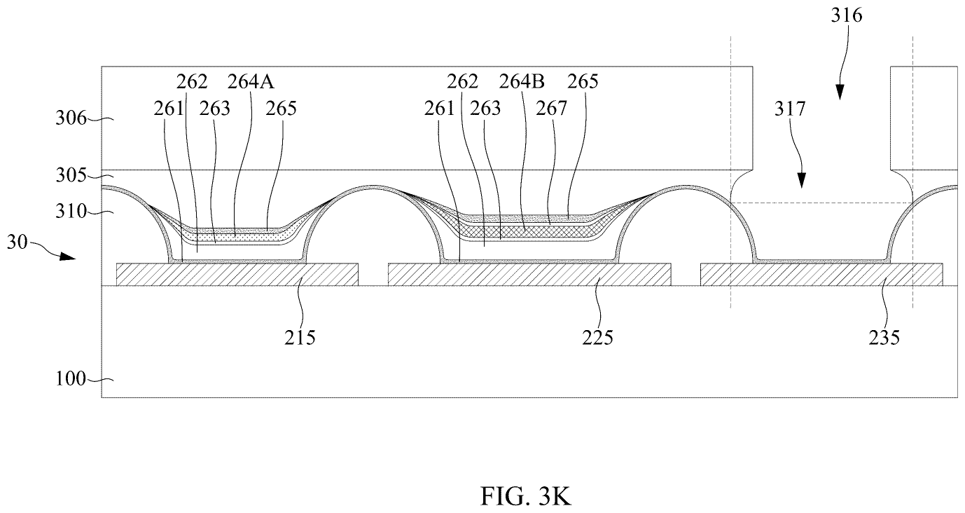

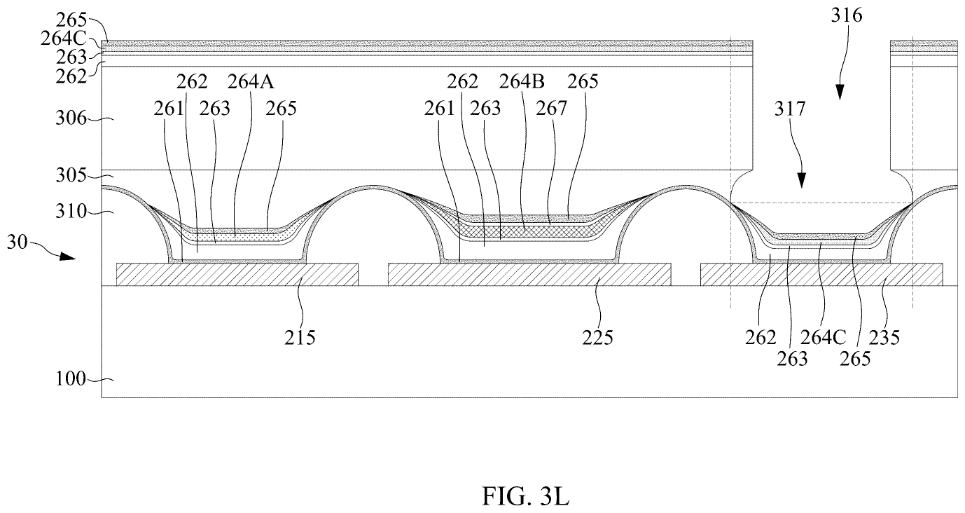

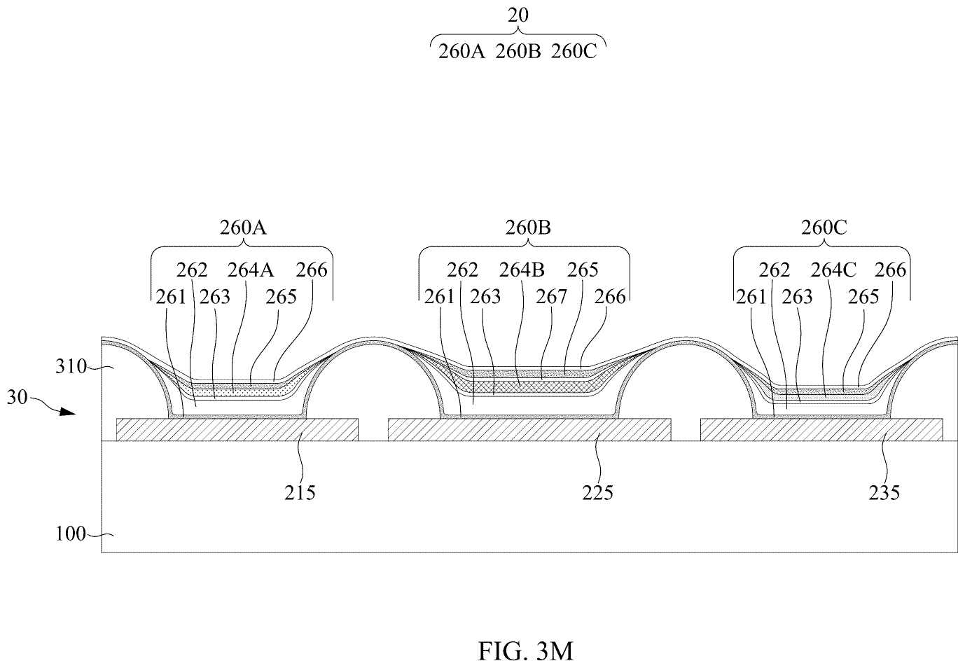

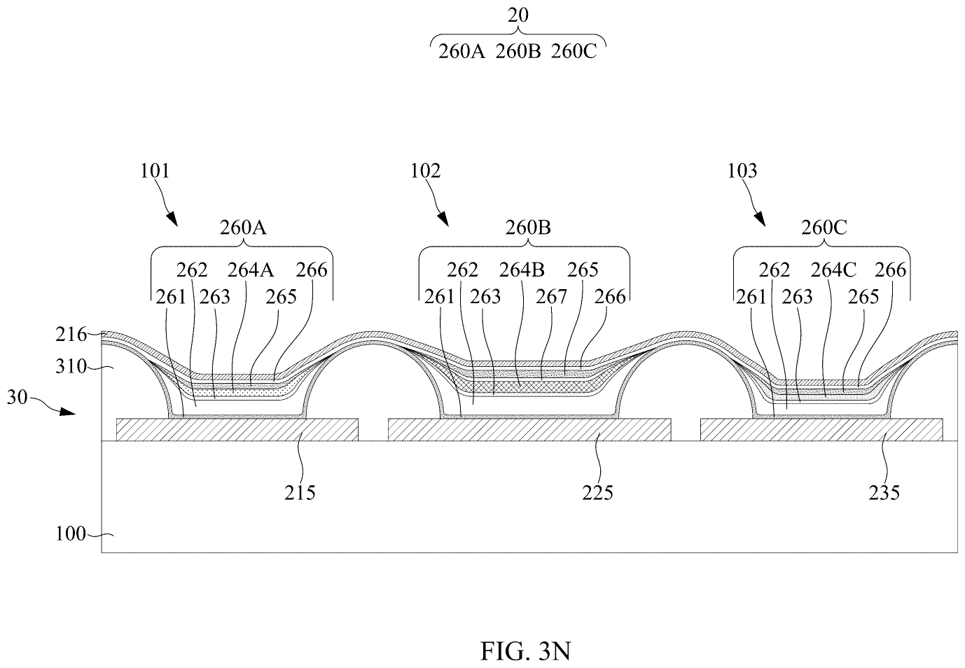

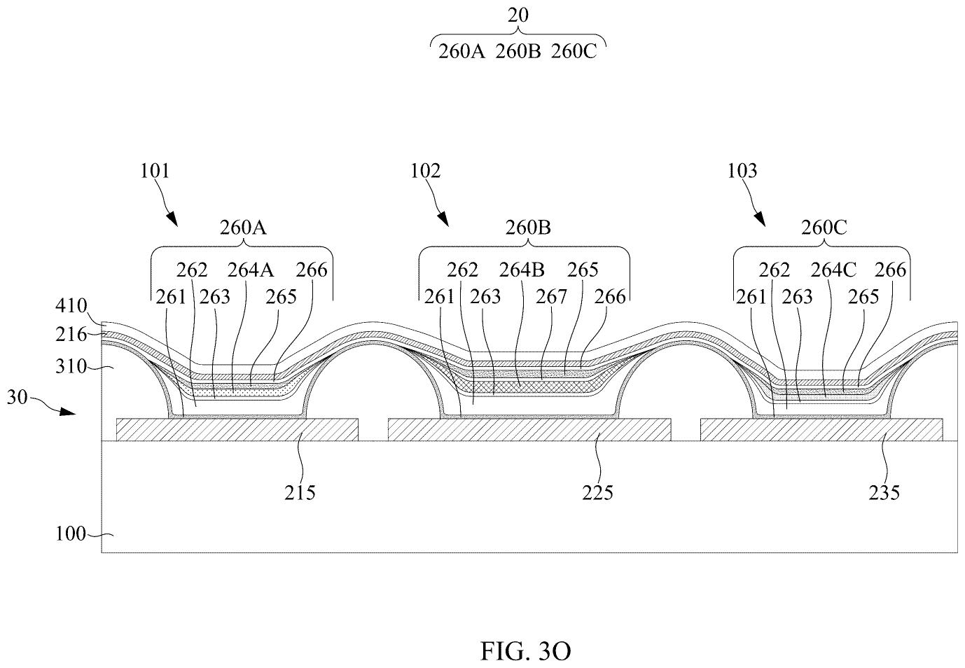

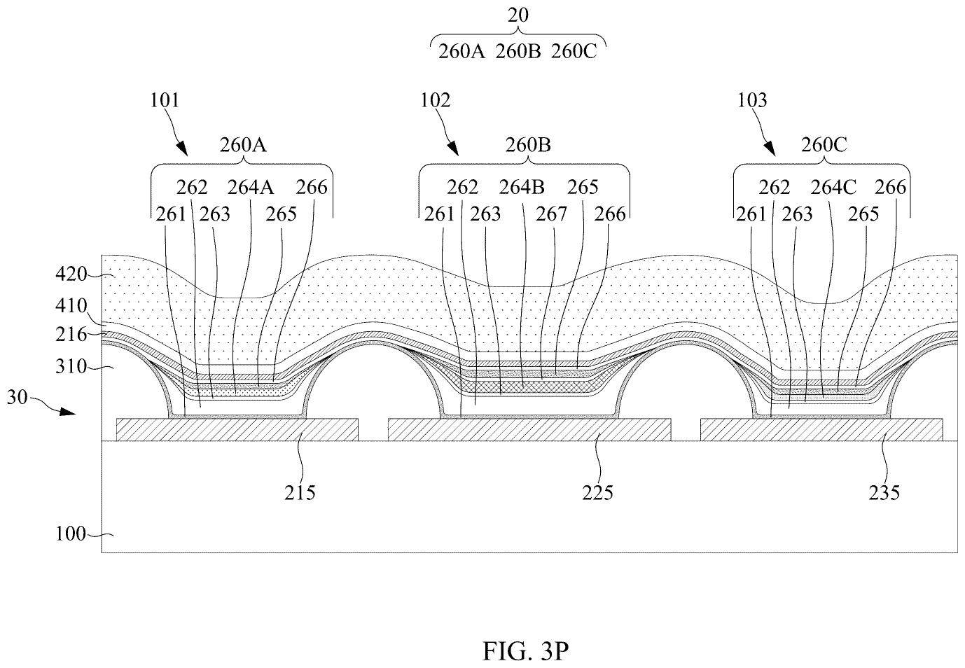

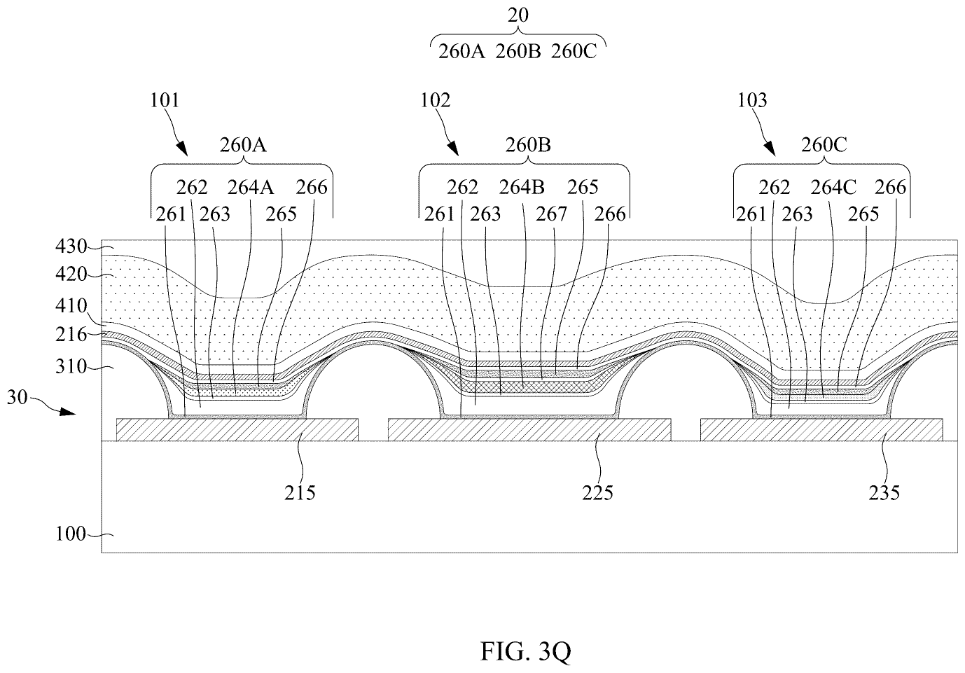

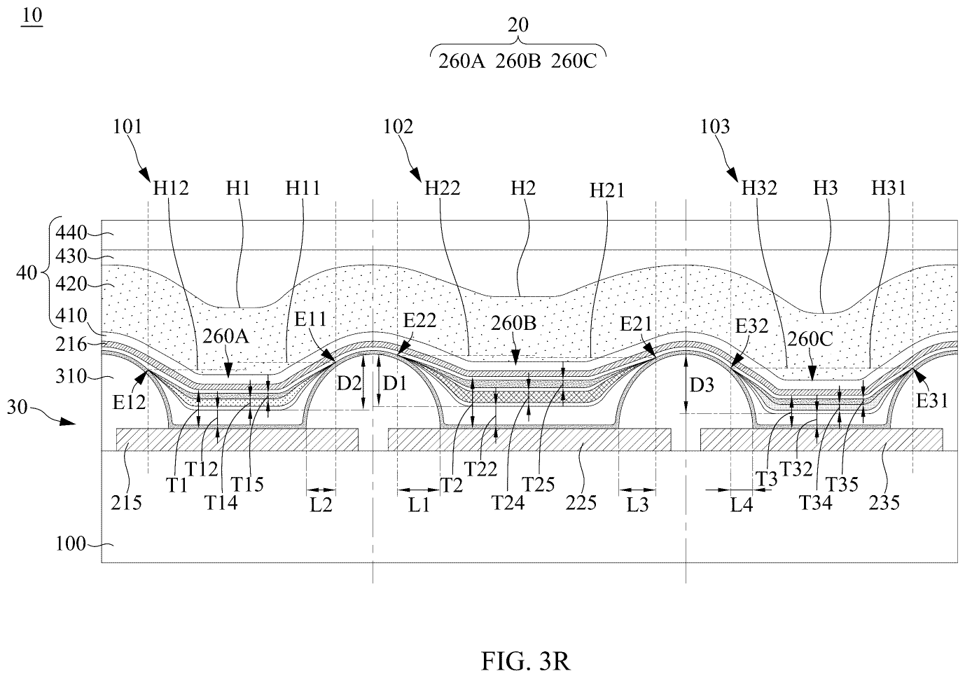

FIG. 3A to FIG. 3R depict a manufacturing method of an organic light emitting element 10 according to some embodiments.

As shown in FIG. 3A, in some embodiments, a substrate 100 is provided, a plurality of electrodes 215, 225 and 235 are disposed over the substrate 100, and a plurality of protrusions 310 (or a spacer structure 30) are formed, wherein each of the protrusions 310 fills a gap between the adjacent electrodes 215, 225 and 235. Next, in some embodiments, a hole injection layer (HIL) 261 is disposed on surfaces of the protrusions 310 and the electrodes 215, 225 and 235. In some embodiments, the hole injection layer (HIL) 261 is formed by means of evaporation.

As shown in FIG. 3B, in some embodiments, a buffer layer 301 is disposed over the protrusions 310, and the buffer layer 301 also covers the hole injection layer (HIL) 261 and the electrodes 215, 225 and 235. The buffer layer 301 is used to block moisture from passing through or entering the protrusions 310 and the hole injection layer 261. Next, in some embodiments, a photosensitive layer 302 is disposed over the buffer layer 301. In some embodiments, the buffer layer 301 and the photosensitive layer 302 are formed by means of coating.

As shown in FIG. 3C, in some embodiments, the photosensitive layer 302 is patterned by a lithography process, such that a portion of the buffer layer 301 is exposed through a groove 312. Next, in some embodiments, a portion of the buffer layer 301 is removed to form a groove 313, so as to expose the hole injection layer (HIL) 261. In some embodiments, the buffer layer 301 is removed by means of a wet etching process.

As shown in FIG. 3D, in some embodiments, a hole transport layer (HTL) 262 is disposed over the hole injection layer (HIL) 261, an electron barrier layer (EBL) 263 is disposed over the hole transport layer (HTL) 262, an organic emission layer (EML) 264A is disposed over the electron barrier layer (EBL) 263, and an electron transport layer (ETL) 265 is disposed over the organic emission layer (EML) 264A. In some embodiments, the hole transport layer (HTL) 262, the electron barrier layer (EBL) 263, the organic emission layer (EML) 264A and the electron transport layer (ETL) 265 are formed by means of evaporation.

As shown in FIG. 3E, in some embodiments, the buffer layer 301, the photosensitive layer 302, and portions of the hole transport layer (HTL) 262, the electron barrier layer (EBL) 263, the organic emission layer (EML) 264A and the electron transport layer (ETL) 265 above the photosensitive layer 302 are removed. In some embodiments, the buffer layer 301, the photosensitive layer 302, a portion of the hole transport layer (HTL) 262, a portion of the electron barrier layer (EBL) 263, a portion of the organic emission layer (EML) 264A and a portion of the electron transport layer (ETL) 265 are removed by means of a wet etching process.

As shown in FIG. 3F, in some embodiments, a buffer layer 303 is disposed over the protrusions 310, and the buffer layer 303 also covers the hole injection layer (HIL) 261 and the electrodes 215, 225 and 235. Next, in some embodiments, a photosensitive layer 304 is disposed over the buffer layer 303.

As shown in FIG. 3G, in some embodiments, the photosensitive layer 304 is patterned by a lithography process, such that a portion of the buffer layer 303 is exposed through a groove 314. Next, in some embodiments, a portion of the buffer layer 303 is removed to form a groove 315, so as to expose the hole injection layer (HIL) 261. In some embodiments, the buffer layer 303 is removed by means of a wet etching process.

As shown in FIG. 3H, in some embodiments, a hole transport layer (HTL) 262 is disposed over the hole injection layer (HIL) 261, an electron barrier layer (EBL) 263 is disposed over the hole transport layer (HTL) 262, an organic emission layer (EML) 264B is disposed over the electron barrier layer (EBL) 263, a hole barrier layer (HBL) 267 is disposed over the organic emission layer (EML) 264B, and an electron transport layer (ETL) 265 is disposed over the hole barrier layer (HBL) 267.

As shown in FIG. 3I, in some embodiments, the buffer layer 303, the photosensitive layer 304, and portions of the hole transport layer (HTL) 262, the electron barrier layer (EBL) 263, the organic emission layer (EML) 264B, the hole barrier layer (HBL) 267 and the electron transport layer (ETL) 265 above the photosensitive layer 304 are removed. In some embodiments, the buffer layer 303, the photosensitive layer 304, a portion of the hole transport layer (HTL) 262, a portion of the electron barrier layer (EBL) 263, a portion of the organic emission layer (EML) 264B, a portion of the hole barrier layer (HBL) 267 and a portion of the electron transport layer (ETL) 265 are removed by means of a wet etching process.

As shown in FIG. 3J, in some embodiments, a buffer layer 305 is disposed over the protrusions 310, and the buffer layer 305 also covers the hole injection layer (HIL) 261 and the electrodes 215, 225 and 235. Next, in some embodiments, a photosensitive layer 306 is disposed over the buffer layer 305.

As shown in FIG. 3K, in some embodiments, the photosensitive layer 306 is patterned by a lithography process, such that a portion of the buffer layer 305 is exposed through a groove 316. Next, in some embodiments, a portion of the buffer layer 305 is removed to form a groove 317, so as to expose the hole injection layer (HIL) 261. In some embodiments, the buffer layer 305 is removed by means of a wet etching process.

As shown in FIG. 3L, in some embodiments, a hole transport layer (HTL) 262 is disposed over the hole injection layer (HIL) 261, an electron barrier layer (EBL) 263 is disposed over the hole transport layer (HTL) 262, an organic emission layer (EML) 264C is disposed over the electron barrier layer (EBL) 263, and an electron transport layer (ETL) 265 is disposed over the organic emission layer (EML) 264C.

As shown in FIG. 3M, in some embodiments, the buffer layer 305, the photosensitive layer 306, and portions of the hole transport layer (HTL) 262, the electron barrier layer (EBL) 263, the organic emission layer (EML) 264C and the electron transport layer (ETL) 265 above the photosensitive layer 306 are removed. In some embodiments, the buffer layer 305, the photosensitive layer 306, a portion of the hole transport layer (HTL) 262, a portion of the electron barrier layer (EBL) 263, a portion of the organic emission layer (EML) 264C and a portion of the electron transport layer (ETL) 265 are removed by means of a wet etching process. Next, in some embodiments, an electron injection layer (EIL) 266 is disposed over the protrusions 310 and the electron transport layer (ETL) 265. Up to this point, the organic light emitting layers 260A, 260B and 260C (or the light emitting layer 20) are formed, and the difference between the thickness T2 of the organic light emitting layer 260B and the thickness T1 of the organic light emitting layer 260A is made to be greater than 500 Å and less than 1500 Å, greater than 700 Å and less than 1500 Å, greater than 600 Å and less than 1300 Å, or greater than 700 Å and less than 1000 Å. In some embodiments, the organic light emitting layers 260A, 260B and 260C (or the light emitting layer 20) are formed, and the difference between the thickness T22 of the hole transport layer 262 of the organic light emitting layer 260B and the thickness T12 of the hole transport layer 262 of the organic light emitting layer 260A is made to be greater than 300 Å and less than 1000 Å, greater than 350 Å and less than 800 Å, or greater than 400 Å and less than 600 Å. In some embodiments, the organic light emitting layers 260A, 260B and 260C (or the light emitting layer 20) are formed, and the difference between the thickness T22 of the hole transport layer 262 of the organic light emitting layer 260B and the thickness T12 of the hole transport layer 262 of the organic light emitting layer 260A is made to be greater than the difference between the thickness T24 of the organic emission layer 264B and the thickness T14 of the organic emission layer 264A.

As shown in FIG. 3N, in some embodiments, an electrode 216 (or a top electrode layer) is disposed over the organic light emitting layers 260A, 260B and 260C and the spacer structure 30. Up to this point, the organic light emitting units 101, 102 and 103 are formed.

As shown in FIG. 3O, in some embodiments, a capping layer 410 is disposed over the electrode 216. In some embodiments, the capping layer 410 is formed by means of evaporation.

As shown in FIG. 3P, in some embodiments, an encapsulation layer 420 is disposed over the capping layer 410. In some embodiments, the capping layer 410 is formed by means of evaporation.

As shown in FIG. 3Q, in some embodiments, a filler layer 430 is disposed over the encapsulation layer 420. In some embodiments, the encapsulation layer 420 is formed by means of plasma enhanced chemical vapor deposition (PECVD).

As shown in FIG. 3R, in some embodiments, a cover plate 440 is disposed over the filler layer 430. Up to this point, a cover layer 40 including the capping layer 410, the encapsulation layer 420, the filler layer 430 and the cover plate 440 is formed. As shown in FIG. 3R, up to this point, the organic light emitting element 10 shown in FIG. 2, FIG. 2A, FIG. 2B and FIG. 2C is formed.

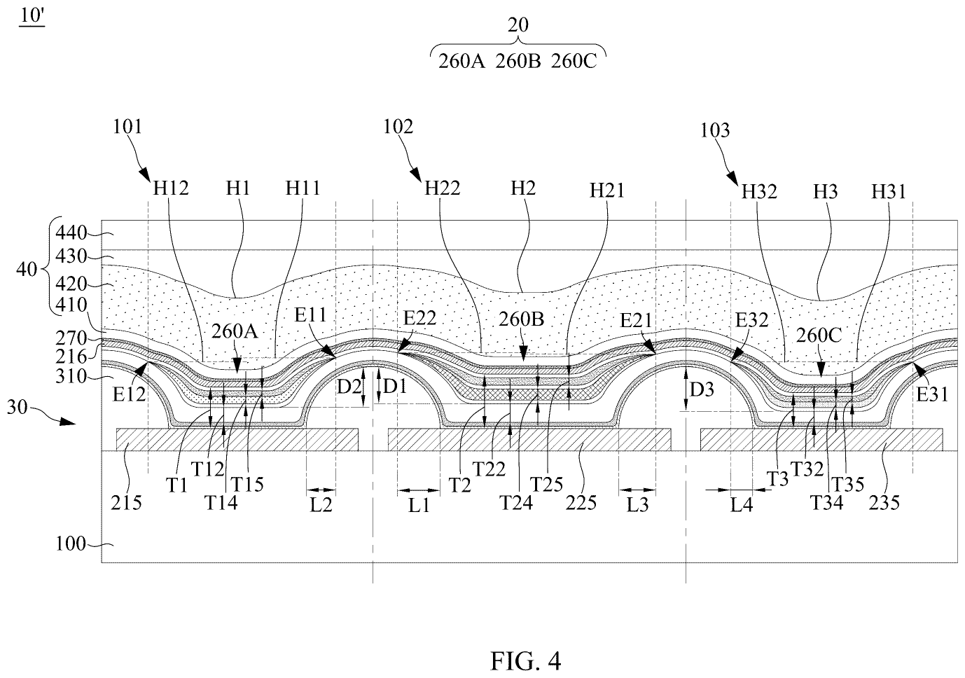

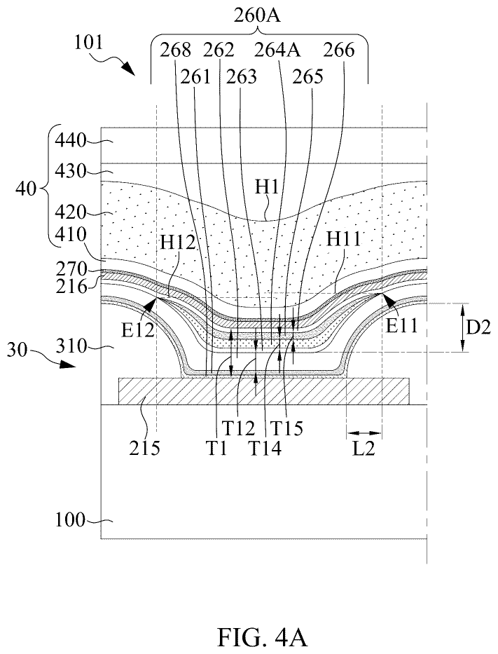

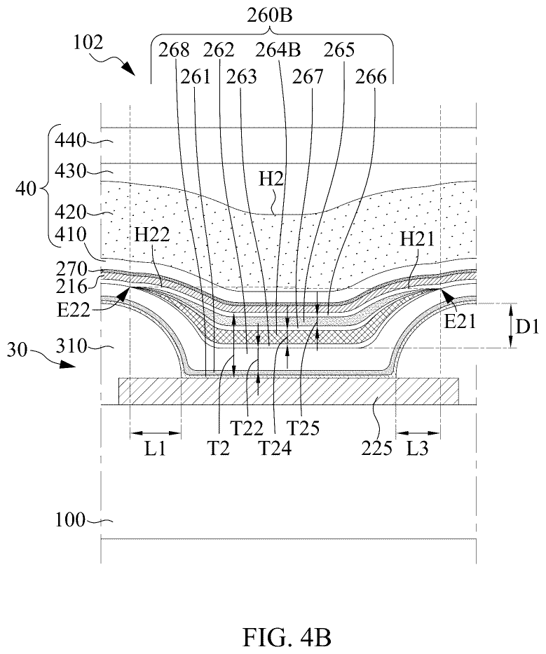

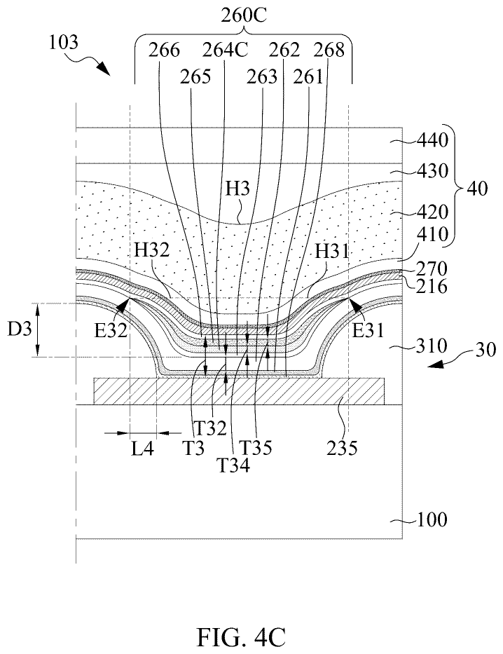

FIG. 4 shows a cross-sectional diagram of an organic light emitting element 10′. FIG. 4A shows a cross-sectional diagram of an organic light emitting unit 101 in FIG. 4. FIG. 4B shows a cross-sectional diagram of an organic light emitting unit 102 in FIG. 4. FIG. 4C shows a cross-sectional diagram of an organic light emitting unit 103 in FIG. 4. In some embodiments, FIG. 4 shows a cross-sectional diagram taken along the line A-A′ in FIG. 1 as an example, and only a light emitting region is illustrated. The structure in FIG. 4 is similar to the structure in FIG. 2, and differences therebetween are described below.

In some embodiments, the organic light emitting element 10′ further includes an inorganic barrier layer 270. In some embodiments, the inorganic barrier layer 270 covers the electrode 216. In some embodiments, the inorganic barrier layer 270 contacts the capping layer 410. In some embodiments, the capping layer 410 is over the inorganic barrier layer 270 and is separated or spaced apart from the electrode 216 by the inorganic barrier layer 270. In some embodiments, the inorganic barrier layer 270 substantially completely covers an interface between the electrode 216 and the capping layer 410. In some embodiments, the inorganic barrier layer 270 includes a transition metal oxide. In some embodiments, the inorganic barrier layer 270 includes molybdenum oxide (MoO₃). In some embodiments, a thickness of the inorganic barrier layer 270 is equal to or less than 50 Å. In some embodiments, a ratio of the thickness of the inorganic barrier layer 270 to the thickness of the electrode 216 is less than 0.15, 0.1 or 0.05. In some embodiments, a ratio of the thickness of the inorganic barrier layer 270 to the thickness of the capping layer 410 is less than 0.5, 0.3 or 0.15.

In some embodiments, the electron transport layer 265 includes an organic electron transport material and an organic barrier material. The organic electron transport material may be different from the organic barrier material. The organic barrier material may include a combination of lithium quinolate (Liq) and a phenanthroline compound. In some embodiments, the phenanthroline compound includes 4,7-diphenyl-1,10-phenanthroline (Bphen), 2,9-bis(naphthalene-2-yl) 4,7-diphenyl-1,10-phenanthroline (NBphen), 1,3-bis(9-phenyl-1,10-phenanthroline-2-yl)benzene), 1,4-bis(2-phenyl-1,10-phenanthroline-4-yl)benzene (p-bPPhenB) and/or 1,3-bis(2-phenyl-1,10-phenanthroline-4-yl)benzene (m-bPPhenB), or any combination of the above. In some embodiments, the electron transport layer 265 is in partial contact with the electrode 216. In some embodiments, the hole injection layer 261, the hole transport layer 262, the electron barrier layer 263 and the organic emission layer 264 are separated or spaced apart from the electrode 216 by the electron transport layer 265.

In some embodiments, each of the organic light emitting layers 260A, 260B and 260C further includes the inorganic barrier layer 268. In some embodiments, the inorganic barrier layer 268 is between the electrodes 215, 225 and 235 and the organic light emitting layers 260A, 260B and 260C. In some embodiments, a side surface of the inorganic barrier layer 268 contacts the protrusion 310. In some embodiments, the inorganic barrier layer 268 substantially completely covers interfaces between the electrodes 215, 225 and 235 and the organic light emitting layers 260A, 260B and 260C. In some embodiments, the inorganic barrier layer 268 includes a transition metal oxide. In some embodiments, the inorganic barrier layer 268 includes molybdenum oxide (MoO₃). In some embodiments, a thickness of the inorganic barrier layer 268 is equal to or less than 50 Å. In some embodiments, a ratio of the thickness of the inorganic barrier layer 268 to the thicknesses of the electrodes 215, 225 and 235 is less than 0.1, 0.06 or 0.03.

In some embodiments, the electron injection layer 266 includes an electron injection material and an inorganic barrier material. The electron injection material may be different from the inorganic barrier material. In some embodiments, the electron injection layer 266 is between the electron transport layer 265 and the electrode 216. The electron injection layer 266 may include a lanthanide element. In some embodiments, the electron injection layer 266 includes ytterbium (Yb). In some embodiments, the electron injection layer 266 is or includes a Yb metal layer.

In some embodiments, the inorganic barrier layer 268 and the hole injection layer 261 may jointly form a hole injection layer of the organic light emitting layers 260A, 260B and 260C.

According to some embodiments of the present disclosure, the inorganic barrier layer 270 may be used to block metal atoms in the electrode 216 from diffusing into an organic layer (for example, the capping layer 410), hence preventing degradation of light emitting efficiency and further enhancing light emitting luminance and improving a color rendering index (Ra) of an organic light emitting element. Moreover, according to some embodiments of the present disclosure, the inorganic barrier layer 270 has an extremely small thickness relative to the electrode 216 and the capping layer 410, and so the size in thickness of the organic light emitting element is not significantly increased and an undesirable increase in a light emitting path is likewise not resulted.

According to some embodiments of the present disclosure, the organic barrier material in the electron transport layer 265 may be used to block metal atoms in the electrode 216 from diffusing into the organic light emitting layers 260A, 260B and 260C (for example, the hole injection layer 261, the hole transport layer 262, the electron barrier layer 263 and the organic emission layer 264) to avoid quenching, hence preventing degradation of light emitting efficiency and further enhancing light emitting luminance and improving a color rendering index (Ra) of an organic light emitting element.

According to some embodiments of the present disclosure, the organic barrier material in the electron transport layer 265 may be used in combination with the inorganic barrier material in the electron injection layer 266. Thus, different barrier characteristics of the organic barrier material and the inorganic barrier material may be combined to complement each other, so as to further block metal atoms in the electrode 216 from diffusing into the organic light emitting layers 260A, 260B and 260C (for example, the hole injection layer 261, the hole transport layer 262, the electron barrier layer 263 and the organic emission layer 264) to avoid quenching, hence preventing degradation of light emitting efficiency and further enhancing light emitting luminance and improving a color rendering index (Ra) of an organic light emitting element.

According to some embodiments of the present disclosure, the inorganic barrier layer 268 may be used to block metal atoms in the electrode 215 from diffusing into the organic light emitting layers 260A, 260B and 260C (for example, the hole injection layer 261, the hole transport layer 262, the electron barrier layer 263 and the organic emission layer 264) to avoid quenching, hence preventing degradation of light emitting efficiency and further enhancing light emitting luminance and improving a color rendering index (Ra) of an organic light emitting element. Moreover, according to some embodiments of the present disclosure, the inorganic barrier layer 268 has an extremely small thickness relative to the electrodes 215, 225 and 235, and so the size in thickness of the organic light emitting element is not significantly increased and an undesirable increase in a light emitting path is likewise not resulted.

According to some embodiments of the present disclosure, the organic light emitting element 10′ includes the inorganic barrier layers 268 and 270, the electron transport layer 265 includes an organic barrier material, and the electron injection layer 266 includes a lanthanide element. Thus, with the structure and combination above, metal atoms in the electrodes 215, 225, 235 and 216 can be effectively prevented from diffusing into the organic light emitting layers 260A, 260B and 260C (for example, the hole injection layer 261, the hole transport layer 262, the electron barrier layer 263 and the organic emission layer 264) to avoid quenching, hence preventing degradation of light emitting efficiency and further enhancing light emitting luminance of an organic light emitting element.

Moreover, according to some embodiments of the present disclosure, the electron injection layer 266 includes Yb and the electron transport layer 265 includes an organic barrier material formed by combining lithium quinolate (Liq) and a phenanthroline compound (for example, p-bPPhenB). Thus, even if the electron transport layer 265 is only partially covered by the electron injection layer 266 and is in partial contact with the electrode 216, the outstanding barrier ability thereof is still capable of effectively blocking metal atoms in the electrode 216 from diffusing into the organic light emitting layers 260A, 260B and 260C, thereby effectively improving light emitting luminance and a color rendering index (Ra) of an organic light emitting element.

The features of some embodiments are described in brief above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the present disclosure, and various changes, substitutions and replacements may be made to the embodiments by a person skilled in the art without departing from the spirit and scope of the present disclosure.

What is claimed is:

1. An organic light emitting element, comprising:
a substrate;
a first electrode and a second electrode over the substrate;
a first organic light emitting layer over the first electrode; and
a second organic light emitting layer over the second electrode;
wherein a difference between a thickness of the second organic light emitting layer and a thickness of the first organic light emitting layer is greater than 500 angstrom (Å) and less than 1500 Å.

2. The organic light emitting element according to claim 1, further comprising:
a third electrode over the substrate; and
a third organic light emitting layer over the third electrode;
wherein a difference between the thickness of the second organic light emitting layer and a thickness of the third organic light emitting layer is greater than 800 Å and less than 1800 Å.

3. The organic light emitting element according to claim 2, wherein a luminescence wavelength of the second organic light emitting layer is greater than a luminescence wavelength of the first organic light emitting layer, and the luminescence wavelength of the first organic light emitting layer is greater than a luminescence wavelength of the third organic light emitting layer.

4. The organic light emitting element according to claim 2, wherein the thickness of the second organic light emitting layer is greater than the thickness of the first organic light emitting layer, and the thickness of the first organic light emitting layer is greater than the thickness of the third organic light emitting layer.

5. The organic light emitting element according to claim 2, wherein the first organic light emitting layer comprises a first hole transport layer, the second organic light emitting layer comprises a second hole transport layer, the third organic light emitting layer comprises a third hole transport layer, a thickness of the second hole transport layer is greater than a thickness of the first hole transport layer, and the thickness of the first hole transport layer is greater than a thickness of the third hole transport layer.

6. The organic light emitting element according to claim 2, wherein the first organic light emitting layer comprises a first electron transport layer, the second organic light emitting layer comprises a second electron transport layer, the third organic light emitting layer comprises a third electron transport layer, a thickness of the second electron transport layer is greater than a thickness of the first electron transport layer and a thickness of the third electron transport layer.

7. The organic light emitting element according to claim 1, wherein the first organic light emitting layer comprises a first hole transport layer, the second organic light emitting layer comprises a second hole transport layer, and a difference between a thickness of the second hole transport layer and a thickness of the first hole transport layer is greater than 300 Å and less than 1000 Å.

8. The organic light emitting element according to claim 1, wherein the first organic light emitting layer comprises a first hole transport layer, the second organic light emitting layer comprises a second hole transport layer, and an elevation of an upper surface of the second hole transport layer is higher than an elevation of an upper surface of the first hole transport layer.

9. The organic light emitting element according to claim 8, further comprising:
a spacer structure over the substrate and between the first organic light emitting layer and the second organic light emitting layer, wherein a vertical distance between the elevation of the upper surface of the second hole transport layer and an elevation of an upper surface of the spacer structure is less than a vertical distance between the elevation of the upper surface of the first hole transport layer and the elevation of the upper surface of the spacer structure.

10. The organic light emitting element according to claim 8, further comprising:
a spacer structure over the substrate and partially covering the first electrode, wherein a first edge of the second hole transport layer and a second edge opposite to the first edge are above the spacer structure and are located at different elevations.

11. The organic light emitting element according to claim 8, further comprising:
a spacer structure over the substrate and between the first organic light emitting layer and the second organic light emitting layer, wherein the first hole transport layer and the second hole transport layer partially cover the spacer structure, and an extension length of the second hole transport layer on the spacer structure is greater than an extension length of the first hole transport layer on the spacer structure.

12. The organic light emitting element according to claim 8, further comprising:
a third electrode over the substrate; and
a third organic light emitting layer over the third electrode and comprising a third hole transport layer, wherein the elevation of the upper surface of the second hole transport layer is higher than an elevation of an upper surface of the third hole transport layer.

13. The organic light emitting element according to claim 1, wherein the difference between the thickness of the second organic light emitting layer and the thickness of the first organic light emitting layer is greater than 700 Å and less than 1500 Å.

14. The organic light emitting element according to claim 13, wherein the difference between the thickness of the second organic light emitting layer and the thickness of the first organic light emitting layer is greater than 700 Å and less than 1000 Å.

15. The organic light emitting element according to claim 1, wherein the first organic light emitting layer comprises an electron transport layer and a hole injection layer, the electron transport layer comprises an organic barrier material, and the hole injection layer comprises a transition metal oxide.

16. The organic light emitting element according to claim 15, further comprising:
a top electrode above the first organic light emitting layer;
an inorganic barrier layer covering the top electrode; and
a capping layer over the inorganic barrier layer and separated from the top electrode by the inorganic barrier layer.

17. A manufacturing method of an organic light emitting element, comprising:
providing a substrate;
disposing a first electrode and a second electrode over the substrate;
forming a first organic light emitting layer over the first electrode; and
forming a second organic light emitting layer over the second electrode to generate a difference between a thickness of the second organic light emitting layer and a thickness of the first organic light emitting layer that is greater than 500 Å and less than 1500 Å.

18. The manufacturing method according to claim 17, further comprising:
forming a spacer structure over the substrate to partially cover the first electrode, wherein the first organic light emitting layer and the second organic light emitting layer partially cover the spacer structure; and
forming a top electrode layer over the spacer structure, the first organic light emitting layer, and the second organic light emitting layer.

19. The manufacturing method according to claim 17, wherein
forming the first organic light emitting layer comprises:
forming a first hole transport layer over the first electrode; and
forming the second organic light emitting layer comprises:
forming a second hole transport layer over the second electrode to generate a difference between a thickness of the second hole transport layer and a thickness of the first hole transport layer that is greater than 300 Å and less than 1000 Å.

20. The manufacturing method according to claim 17, wherein
forming the first organic light emitting layer comprises:
forming a first hole transport layer over the first electrode; and
forming a first organic emission layer over the first hole transport layer; and
forming of the second organic light emitting layer comprises:
forming a second hole transport layer over the second electrode; and
forming a second organic emission layer over the second hole transport layer to generate a difference between a thickness of the second hole transport layer and a thickness of the first hole transport layer that is greater than a difference between a thickness of the second organic emission layer and a thickness of the first organic emission layer.
